(19) United States
(12) Patent Application Publication
(10) Pub. No.: US 2017/0247256 A1
(43) Pub. Date: Aug. 31, 2017

(54) ULTRA-HIGH DENSITY SINGLE-WALLED CARBON NANOTUBE HORIZONTAL ARRAY AND ITS CONTROLLABLE PREPARATION METHOD

(71) Applicant: PEKING UNIVERSITY, Beijing (CN)

(72) Inventors: Jin ZHANG, Beijing (CN); Yue HU, Beijing (CN); Lixing KANG, Beijing (CN); Qiuchen ZHAO, Beijing (CN); Shuchen ZHANG, Beijing (CN)

(21) Appl. No.: 15/523,341

(22) PCT Filed: Nov. 21, 2014
(86) PCT No.: PCT/CN2014/001040

§ 371 Date: Apr. 28, 2017

(30) Foreign Application Priority Data
Oct. 29, 2014 (CN) 201410594881.4

(51) Int. Cl. H01L 51/00; C30B 25/18; C30B 29/02; C30B 29/20; C30B 31/04; H01L 51/05; C23C 16/26; C23C 16/02; C23C 16/455; B05D 1/00; B05D 3/04; B05D 3/00; C01B 31/02

(52) U.S. Cl. CPC C01B 31/0233; H01L 51/0002; H01L 51/0048; H01L 51/0566; H01L 51/0541; C30B 25/186; C30B 29/02; C30B 29/20; C30B 31/04; C23C 16/26; C23C 16/0272; C23C 16/45512; B05D 1/005; B05D 3/0453; B05D 3/0406; B05D 3/007; B05D 1/60; C01B 2202/02; B82Y 40/00

(57) ABSTRACT

The present invention discloses single-walled carbon nanotubes horizontal arrays with ultra-high density and the preparation method. The method comprises the following steps: loading a catalyst on a single crystal growth substrate; after annealing, introducing hydrogen into a chemical vapor deposition system to conduct a reduction reaction of the catalyst; and maintaining the introduction of the hydrogen to conduct the orientated growth of a single-walled carbon nanotube. The density of the ultra-high density single-walled carbon nanotube horizontal array obtained by this method exceeds 130 tubes/micrometer, and an electrical performance test is performed on the prepared ultra-high density single-walled carbon nanotube horizontal array shows a high on-current density of 380 μA/μm, and the transconductance of 102.5 μS/μm.

### TECHNICAL FIELD

The present invention belongs to semiconductor field, and relates to an ultra-high density single-walled carbon nanotube horizontal array and its controllable preparation method.

### BACKGROUND

Single-walled carbon nanotubes (SWNTs) have attracted great concerns of nanotechnology researchers since they were found in 1993 due to their special structures and excellent properties. Owing to their high toughness, strong electrical conductivity, excellent field emission property, and metallic and semiconducting properties, SWNTs, referred to as “super fiber”, are considered as one of the host materials in nano-electronic devices at post-Moore era. At present, an extensive research is being conducted on potential applications of SWNTs, including quantum wire, electronic device, composite material, electroluminescence, photoluminescence, chemical sensor, nanoparticle carrier and so on.

As for chip industry, traditional transistors are made up of silicon. However, with the development of the technology, more and more micro-transistors are integrated onto a single chip, the yield of good product in production and processing is reduced. Silicon transistor is already close to atomic level and reaches to its physical limit, and it is very difficult to get breakthrough on the running speed and performance of the silicon transistor. Scientists are looking for a new material which can replace silicon in traditional chips so as to continue Moore's law. Carbon nanotube is one of the promising materials which are most likely to replace semiconductor silicon.

In 2012, the scientists of IBM Washington research center had utilized carbon nanotubes to replace semiconductor silicon and achieved the construction of 9 nm carbon nanotube-based field effect transistor. In the same year, they accurately positioned more than ten thousand carbon nanotubes transistors in one chip by using a standard mainstream in semiconductor process, and the test had passed successfully. The more accuracy the positioning of carbon nanotubes is, the more likely they are to be used in semiconductor device of computer chips. In 2013, a scientific research team from Stanford University achieved a breakthrough in the field of a new generation electronic device. They manufactured a first computer prototype using carbon nanotubes in the world for the first time, which consists of 178 carbon nanotube field effect transistors and each transistor containing 10-200 carbon nanotubes, and it can fulfill some tasks such as counting, sequencing, function switching, etc.

As for carbon nanotube-based field effect transistor, the selectivity of semiconducting single-walled carbon nanotubes and density of carbon nanotube array are the main factors to restrict the increase of performance. In 2012, the scientists of IBM research center clearly pointed out that, as shown in FIG. 1, the density of carbon nanotube array will reach to 125 tubes/micrometer and the content of metallic carbon nanotube will be less than 0.0001% by 2020. At present, there are many researches on the increase of density of carbon nanotube array, mainly including direct growing and post-pretreatment. As for the direct growing method, the currently reported density did not meet the requirement yet; as for the post-pretreatment method, the short length, the surface contamination and the less flatness should be improved in the future. Therefore, it is urgent to develop a controllable preparation method to obtain ultra-high density single-walled carbon nanotube horizontal array directly, which is of great importance for both fundamental research and large-scale application of carbon nanotubes.

### THE SUMMARY OF INVENTION

The purpose of the present invention is to provide an ultra-high density single-walled carbon nanotube horizontal array and its controllable preparation method.

The method for preparing the ultra-high density single-walled carbon nanotube horizontal array provided by the present invention comprises the following steps:

loading a catalyst on a single crystal growth substrate; after annealing, introducing hydrogen into a chemical vapor deposition system to conduct a reduction reaction of the catalyst; and maintaining the introduction of the hydrogen to conduct the orientated growth of the single-walled carbon nanotubes, then after the growth is completed, the ultra-high density single-walled carbon nanotube horizontal array is directly obtained on the single crystal growth substrate.

In the above method, the material constituting the single crystal growth substrate is ST-cut quartz, R-cut quartz, a-plane a alumina, r-plane a alumina or magnesium oxide.

The catalyst is selected from at least one of Fe, Co, Ni, Cu, Au, Mo, W, Ru, Rh, and Pd nanoparticles.

The particle size of the catalyst is 1 nm-3 nm.

The above metal nanoparticles can be prepared through a high temperature reduction reaction of the salt solution of the above metals.

The method also comprises the following steps: prior to the step of loading catalyst, pretreating the single crystal growth substrate.

The pre-treating particularly comprises the following steps:

the single crystal growth substrate is successively ultrasonic cleaned in secondary water, acetone, ethanol, and secondary water respectively for 10 min; after blow-dried with nitrogen, the temperature is evaluated to 1000° C.-1500° C. from room temperature within 1.5 h-3 h, and is kept constant-temperature for 4 h-8 h, then the temperature is cooled to 300° C. within 3 h-10 h, followed by naturally cooled to room temperature.

The purpose of this pre-treating step is to clean the single crystal growth substrate and repair the lattice defects generated in the production and processing of the single crystal growth substrate.

In the step of loading the catalyst, the loading method comprises spin-coating or drop-coating the salt solution of the catalyst onto the surface of the single crystal growth substrate.

The salt solution of the catalyst which is spin-coated or drop-coated onto the surface of the single crystal growth substrate is reduced under the treatment of hydrogen in chemical vapor deposition process after annealing, and thereby the catalyst consisting of metal nanoparticles are finally obtained.

In the salt solution of the catalyst, the solute is hydroxide or salt of the metal elements described above, particularly Fe(OH)₃ or (NH₄)₆Mo₇O₄;

In the salt solution of the catalyst, the solvent is selected from at least one of ethanol, water and acetone.

In the salt solution of the catalyst, the salt concentration of the catalyst is 0.01-0.5 mmol/L.

In the spin-coating method, the rotating speed of the spin-coating is particularly 1000-5000 rpm, and more particularly 2000 rpm.

The spin-coating time is 1-10 min, and particularly 1 min.

The annealing comprises the following steps:

in air atmosphere, the temperature is evaluated to annealing temperature from room temperature within 1.5 h-3 h, and kept constant for 4 h-48 h; then the temperature is cooled to 300° C. within 3 h-10 h, and then naturally cooled to room temperature.

The annealing temperature is particularly 1100° C., and the time of constant temperature is particularly 8 h.

The purpose of the annealing step is to store the catalyst into the single crystal growth substrate.

In the reduction reaction of the catalyst, the reduction atmosphere is hydrogen atmosphere; the gas flow of hydrogen is particularly 30 sccm-300 sccm, and more particularly 100 sccm-300 sccm.

The reduction time is 1 min-30 min, and particularly 5 min.

The purpose of this reduction reaction is mainly to reduce the catalyst into metal nanoparticles and release them onto the surface of the single crystal growth substrate.

In the orientated growth step of the single-walled carbon nanotubes, the used carbon sources are CH₄, C₂H₄, or ethanol; the carbon source, ethanol, is produced by bubbling liquid ethanol with Ar.

The gas flow of the carbon source is 10 sccm-200 sccm, and particularly 50 sccm-150 sccm.

The growth time is 10 s-1 h, and particularly 10 min-30 min.

In the reduction reaction step and the orientated growth step of the single-walled carbon nanotubes, the temperatures are both 600° C.-900° C., and particularly 830° C.-850° C.

The used carrier gases are both Ar; and the gas flow of the Ar is particularly 50 sccm-500 sccm, and more particularly 300 sccm.

The method also comprises the following steps: after the orientated growth step of the single-walled carbon nanotubes, cooling the system.

The cooling is particularly naturally cooling or program-controlled cooling.

In addition, the ultra-high density single-walled carbon nanotube horizontal array prepared according to the above method, as well as the field effect transistor device containing the ultra-high density single-walled carbon nanotube horizontal array, and using the ultra-high density single-walled carbon nanotube horizontal array in the preparation of the field effect transistor device also belong to the protection scope of the present invention. Wherein, the density of the ultra-high density single-walled carbon nanotube horizontal array is 50-150 tubes/micrometer, and can be particularly 100-150 tubes/micrometer, 130-150 tubes/micrometer.

The difficulties for preparing high density single-walled carbon nanotubes lie in aggregation and inactivation of the catalyst in growth process, thus resulting in that the density of single-walled carbon nanotube horizontal array obtained by direct growth is not high. In the method for preparing ultra-high density single-walled carbon nanotube horizontal array provided by the present invention, the catalyst is stored underneath the surface of the substrate, and gradually released in the growth process, simultaneously growing and releasing ensuring the activity of the catalyst which does not start to catalyze the growth of the carbon nanotubes, thus to obtain an ultra-high density single-walled carbon nanotube horizontal array. Specifically, as shown in FIG. 1, first the catalyst is stored underneath the surface of the substrate (FIG. 1b); then the catalyst is gradually released under a certain condition (FIG. 1c); the carbon nanotubes is grown (FIG. 1d); and the growth is continued with adding carbon source, and new catalyst is released from the substrate in the growth process to continuously catalyzes the growth of the carbon nanotubes (figure le), and thus the ultra-high density single-walled carbon nanotube horizontal array is obtained by direct growth.

Atomic force microscope (AFM) and scanning electron microscope (SEM) are employed to characterize the ultra-high density single-walled carbon nanotube horizontal array prepared by the present invention. AFM and SEM images both clearly show that the density of the prepared high density single-walled carbon nanotubes horizontal array exceeds 130 tubes/micrometer, which is the highest density of single-walled carbon nanotubes horizontal array by direct growth reported at present in the world. Electrical performance test is performed on the ultra-high density single-walled carbon nanotube horizontal array prepared by the present invention, and its on-current density is up to 380 μA/μm, and the transconductance is up to 102.5 μS/μm, the both being the highest level in the carbon nanotube field effect transistor in the world at present. It also shows the high quality and high density of ultra-high density single-walled carbon nanotube horizontal array prepared by the present invention.

### BRIEF DESCRIPTION OF THE FIGURES

FIG. 1 is a flow scheme to prepare ultra-high density single-walled carbon nanotube horizontal arrays.

FIG. 2 is AFM image of the growth substrate: a-plane a alumina single crystal substrate of an ultra-high density single-walled carbon nanotube horizontal array. a) is AFM image of the single crystal growth substrate before annealing, and b) is AFM image of the single crystal growth substrate after annealing.

FIG. 3 is SEM images of the ultra-high density single-walled carbon nanotube horizontal array in example 1, wherein, a), b), c), and d) are respective SEM images at different magnifications.

FIG. 4 is AFM images of the ultra-high density single-walled carbon nanotube horizontal array in example 1, wherein, a), b), c), and d) are respective AFM images at different magnifications.

FIG. 5 is SEM and AFM images of the ultra-high density single-walled carbon nanotube horizontal array in example 2; wherein, a), b), c), and d) are respective SEM images at different magnifications; e) and f) are respective AFM images at different magnifications. FIG. 6 is XPS depth analysis data plot of the single crystal growth substrate which loads Fe catalyst and is annealed in a muffle furnace.

FIG. 7 is AFM images of the growth substrate of ultra-high density single-walled carbon nanotube horizontal array, wherein a) after spin-coating Fe catalyst, b) after annealing a), c) reducing b) with hydrogen for 5 min, d) reducing b) with hydrogen for 10 min, and e) reducing b) with hydrogen for 30 min.

FIG. 8 is SEM images of single-walled carbon nanotube horizontal array for different growth time, wherein a) for 5 min of growth time, carbon nanotube density is less than 1 tube/micrometer, b) for 10 min of growth time, carbon nanotube density is about 10 tubes/micrometer, and c) for 30 min of growth time, carbon nanotube density is more than 100 tubes/micrometer.

FIG. 9 are the performance plots of carbon nanotube field effect transistor prepared based on ultra-high density single-walled carbon nanotube horizontal array, wherein a) is the transfer characteristic curve, and b) is the output characteristic curve.

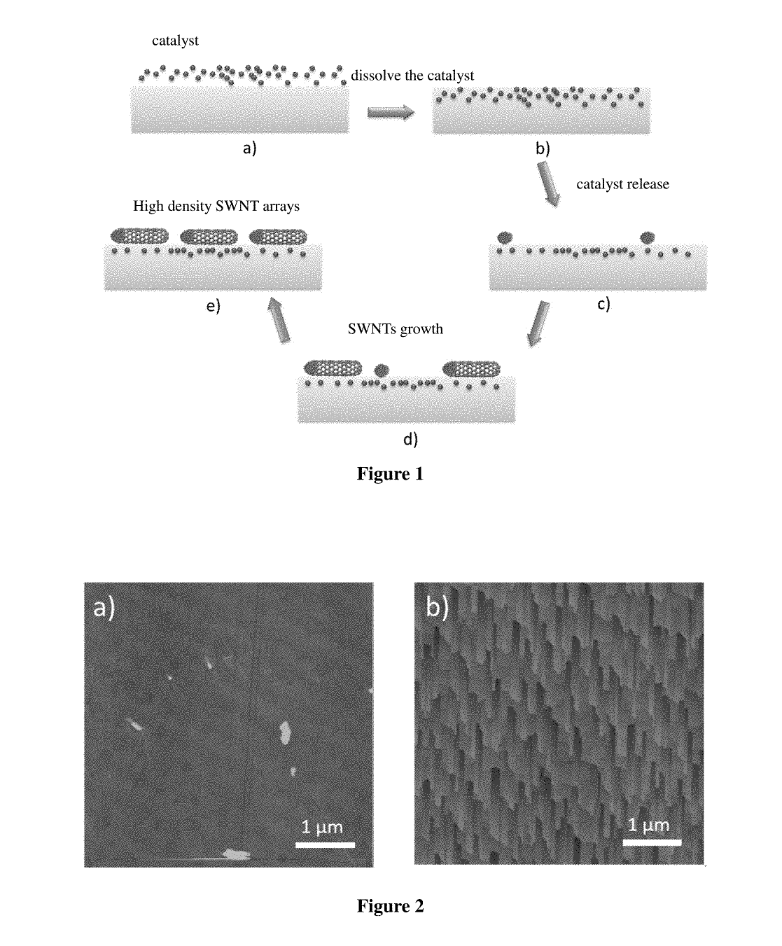

### THE BEST MODE FOR CARRYING OUT THE INVENTION

The present invention will be further illustrated in combination with specific examples below, but the present invention is not limited to the following examples. Unless specially indicated, all the methods are conventional methods. Unless specially indicated, all the raw materials are commercially available.

### Example 1. The Growth of an Ultra-High Density Single-Walled Carbon Nanotube Horizontal Array

1) the pretreating of the single crystal growth substrate;

A-plane α alumina single crystal substrate is selected as the substrate for growing carbon nanotubes, and it is cut into a size of 4 mm×6 mm, wherein the side of 4 mm length is parallel to [0001] direction, and the side of 6 mm length is parallel to [1-100] direction. This substrate is pretreated as follows:

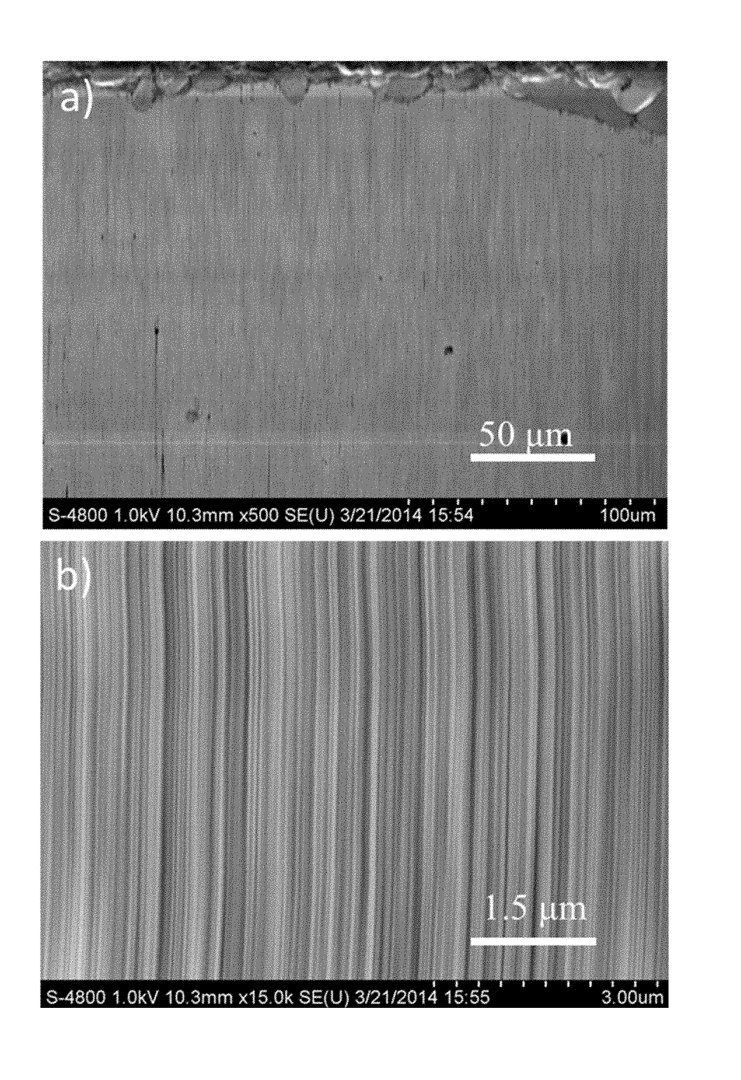

successively ultrasonic cleaning in secondary water, acetone, ethanol, and secondary water respectively for 10 min, and then blow-dried with high purity nitrogen, and its surface morphology is shown as FIG. 2a);

placing the cleaned substrate into a muffle furnace, and elevating the temperature from room temperature to 1100° C. within 2 h, then keeping 1100° C. of constant temperature for 8 h, then cooling to 300° C. within 10 h, and then naturally cooling to room temperature, so as to obtain a pretreated single crystal growth substrate, and its surface morphology is shown as FIG. 2b).

2) the preparation of a high efficient catalyst for growing single-walled carbon nanotubes;

Fe(OH)₃/EtOH solution is selected as a catalyst precursor for growing single-walled carbon nanotubes. 0.3223 g FeCl₃ is weighted and dissolved into 20.0 mL water with stirring to dissolve completely. This solution, 5.0 ml, is drawn and drop-wise dropped into 175 mL boiling water, and the color of the solution slowly turns into nacarat from orange, indicating that FeCl₃ has begun to hydrolyze, and Fe(OH)₃ colloid is generating. The solution is continuously kept for slight boiling for 2 h, and is cooled to room temperature to obtain Fe(OH)₃ colloid solution. This colloid solution is transferred using a pipettor and diluted in ethanol, to a 0.05 mmol/L concentration of Fe(OH)₃ in Fe(OH)₃/EtOH solution, and the solution is ultrasonic treated for 10 min such that it is mixed uniformly, for using in future.

3) the loading of catalyst;

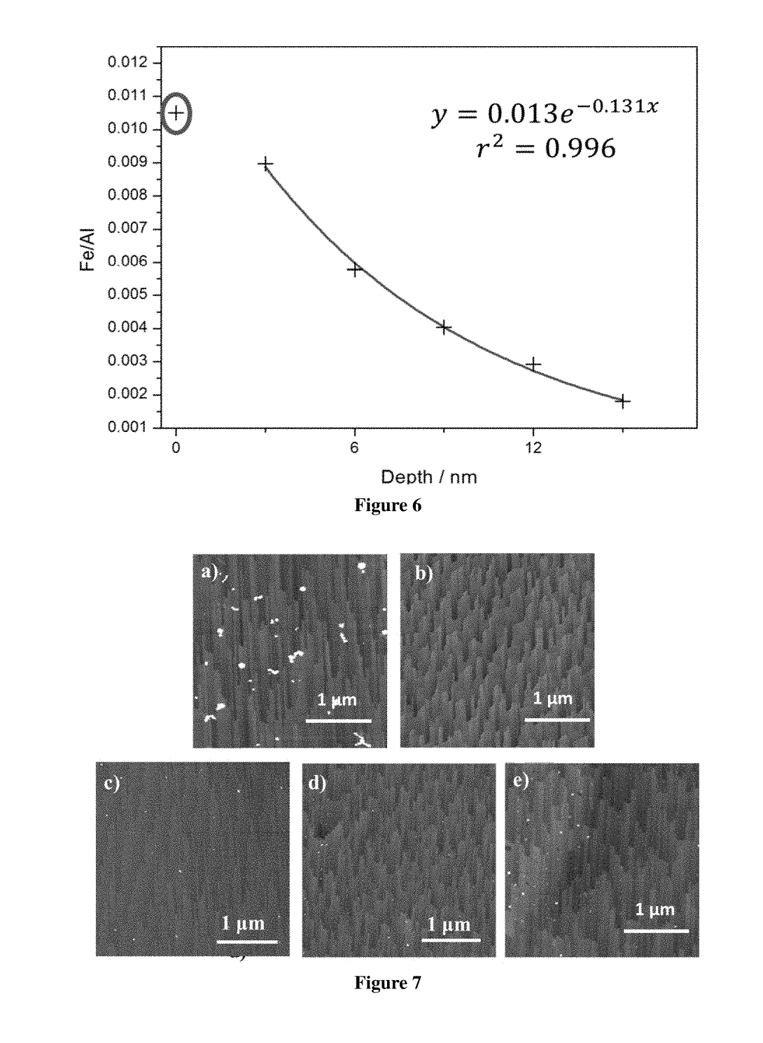

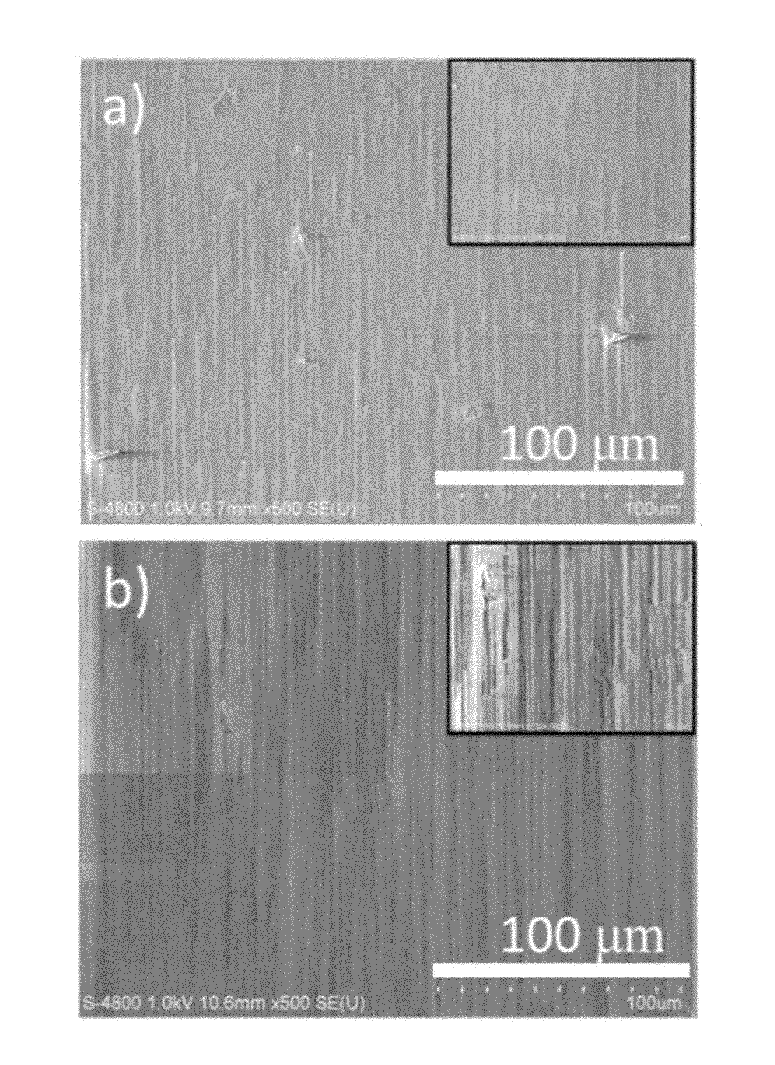

The catalyst is loaded on the single crystal growth substrate by employing the spin-coating method. The pretreated a-plane a alumina single crystal substrate obtained in step 1) is placed on a spin coater, and is fixed by using a mechanical pump; a drop of Fe(OH)₃/EtOH solution obtained in step 2) is taken to drop onto the surface of the substrate, and speed of the spin coater is set as follows: pre-accelerating to 500 rpm within the first 10 seconds then accelerating to 2000 rpm, for spin-coating for 1 min, that is, the catalyst containing Fe is loaded on the surface of the a-plane α alumina single crystal substrate, and its specific morphology is shown as FIG. 7a).

Catalyst particles in the catalyst colloid solution can be effectively uniformly dispersed on the surface of the substrate by using the spin-coating method, and density of the catalyst particles on the substrate of the surface can be controlled by employing different concentrations of catalyst and different rotating speeds of the spin coater. The purpose of diluting Fe(OH)₃ colloid with ethanol is to allow the solvent to be more easily volatilized in the spin-coating process, such that the nanoparticles of the catalyst are dispersed more uniformly.

4) annealing

A-plane α alumina single crystal substrate which is spin-coated with Fe(OH)₃/EtOH solution obtained in step 3) is placed into a muffle furnace to undergo an annealing at high temperature in air atmosphere. Specifically, the temperature is elevated to 1100° C. from room temperature within 2 h, and is kept constant at 1100° C. for 8 h, then is cooled to 300° C. within 10 h, followed by naturally cooled to room temperature to finish the annealing step, and the XPS detection result of the resulting single crystal substrate is shown as FIG. 6;

5) the oriented growth of single-walled carbon nanotubes using a chemical vapor deposition method:

The single crystal growth substrate obtained in step 4) is placed into a chemical vapor deposition system, and the temperature is elevated to the growth temperature 830° C. in the air at a temperature rate of 40° C./min, then 300 sccm argon gas is introduced to evacuate air for 5 min, and 100 sccm H₂ is sequentially introduced for 5 min to reduce and precipitate the catalyst nanoparticles. 50 sccm Ar/EtOH (Ar/EtOH refers to being introduced into liquid ethanol with Ar bubbling) is then introduced to start the oriented growth of single-walled carbon nanotubes, and the growth time is 10 min. The introduction of carbon source is stopped after finishing the growth, with continuously introducing hydrogen and Ar, and naturally cooling to room temperature to obtain the ultra-high density single-walled carbon nanotube horizontal array provided by the present invention.

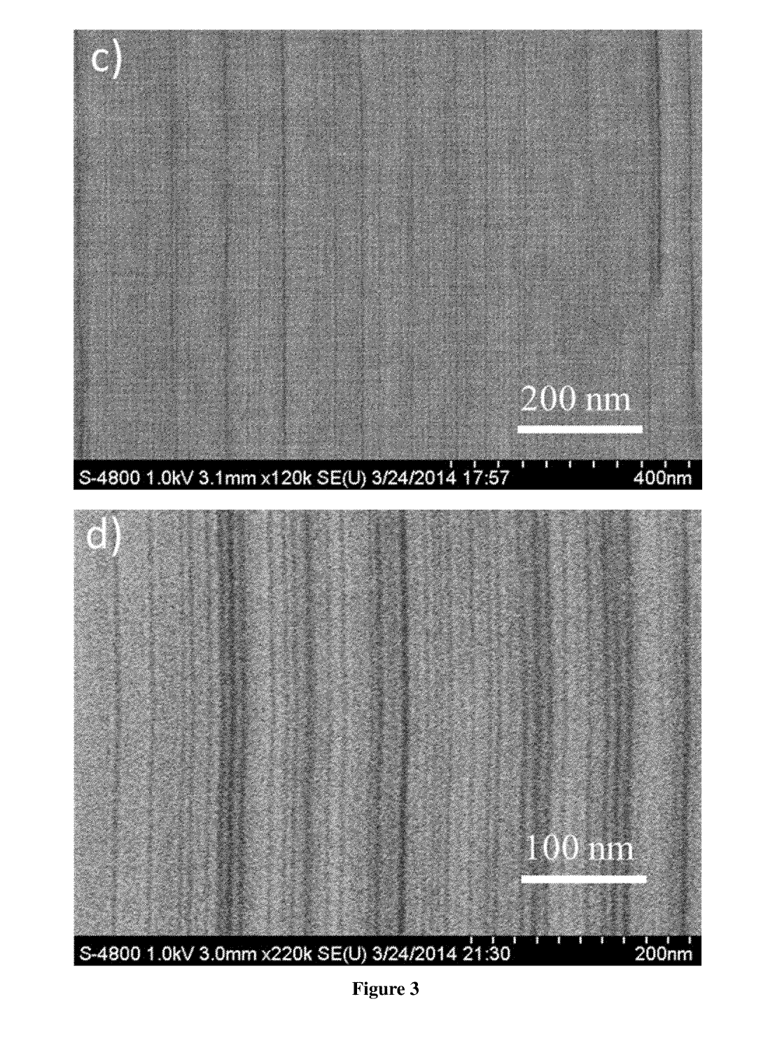

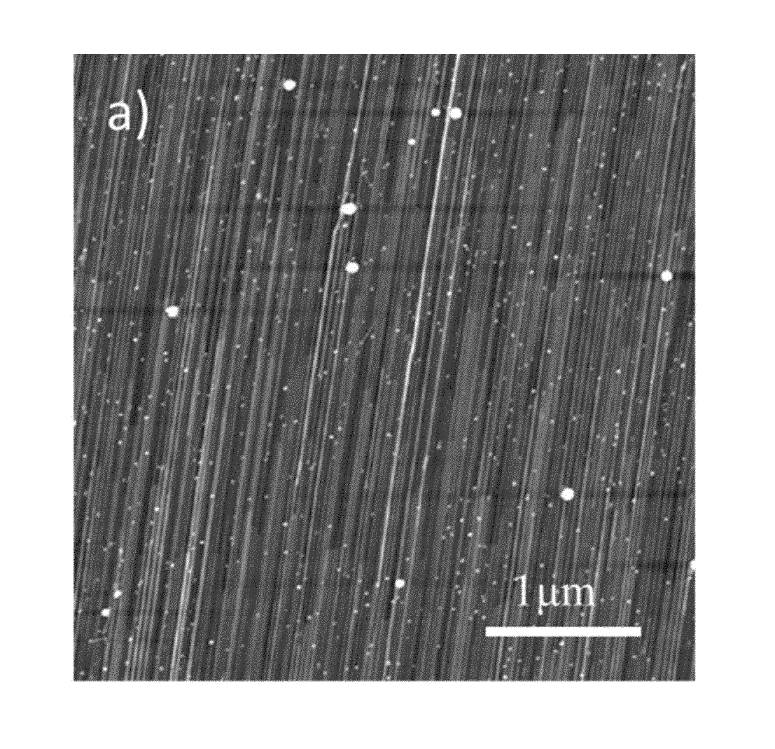

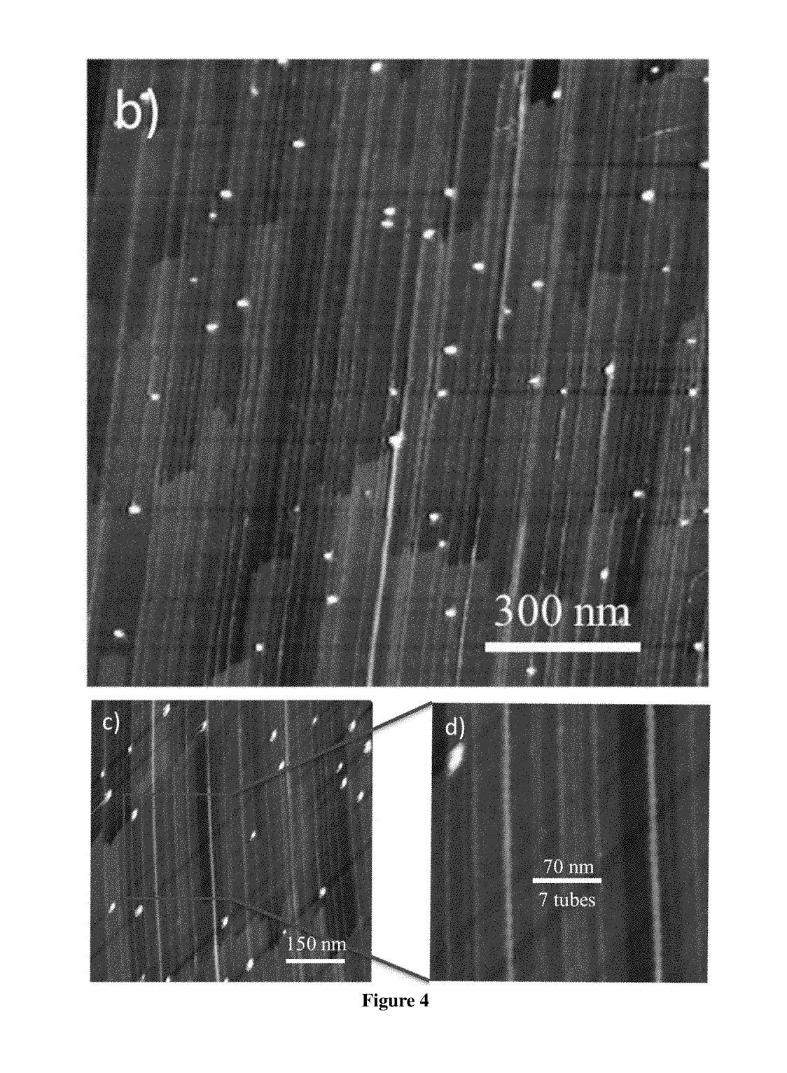

The growth result of the ultra-high density single-walled carbon nanotube horizontal array obtained in this example is shown as FIGS. 3-4. It can be seen from the figures that both AFM and SEM images clearly indicate that the density of single-walled carbon nanotube horizontal array obtained in this example exceeds 130 tubes/micrometer, which is the highest density of single-walled carbon nanotube horizontal array by direct growth reported at present in the world.

### Example 2. The Growth of an Ultra-High Density Single-Walled Carbon Nanotube Horizontal Array

step 1): which is same as the step 1 in example 1;

steps 2) and 3): after the Fe(OH)₃/EtOH solution used in example 1 is replaced with a (NH₄)₆Mo₇O₄/EtOH solution of (NH₄)₆Mo₇O₄ with a concentration of 0.01 mmol/L, it is spin-coated on a-plane α alumina single crystal substrate according to step 3) in example 1, that is, the catalyst containing Mo is loaded on the surface of this a-plane α alumina single crystal substrate.

4) annealing

This substrate is placed into a muffle furnace to undergo an annealing at high temperature in the air, the temperature being elevated to 1000° C. from room temperature within 1.5 h, and kept constant at 1000° C. for 16 h, then cooled to 300° C. within 10 h, followed by naturally cooled to room temperature to complete the annealing step.

5) the oriented growth of single-walled carbon nanotubes using a chemical vapor deposition method:

the single crystal growth substrate obtained in step 4) is placed into a chemical vapor deposition system, and the temperature is elevated to the growth temperature 850° C. in the air at a temperature rate of 30° C./min, then 300 sccm argon gas is introduced to evacuate air for 5 min, and 300 sccm H₂ is sequentially introduced for 5 min to reduce and precipitate the catalyst nanoparticles. 150 sccm Ar/EtOH (Ar/EtOH refers to being introduced into liquid ethanol with Ar bubbling) is then introduced to start the oriented growth of single-walled carbon nanotubes, and the growth time is 30 min. The carbon source is stopped after finishing the growth, with continuously introducing hydrogen and Ar, and naturally cooling to room temperature to obtain the ultra-high density single-walled carbon nanotube horizontal array provided by the present invention.

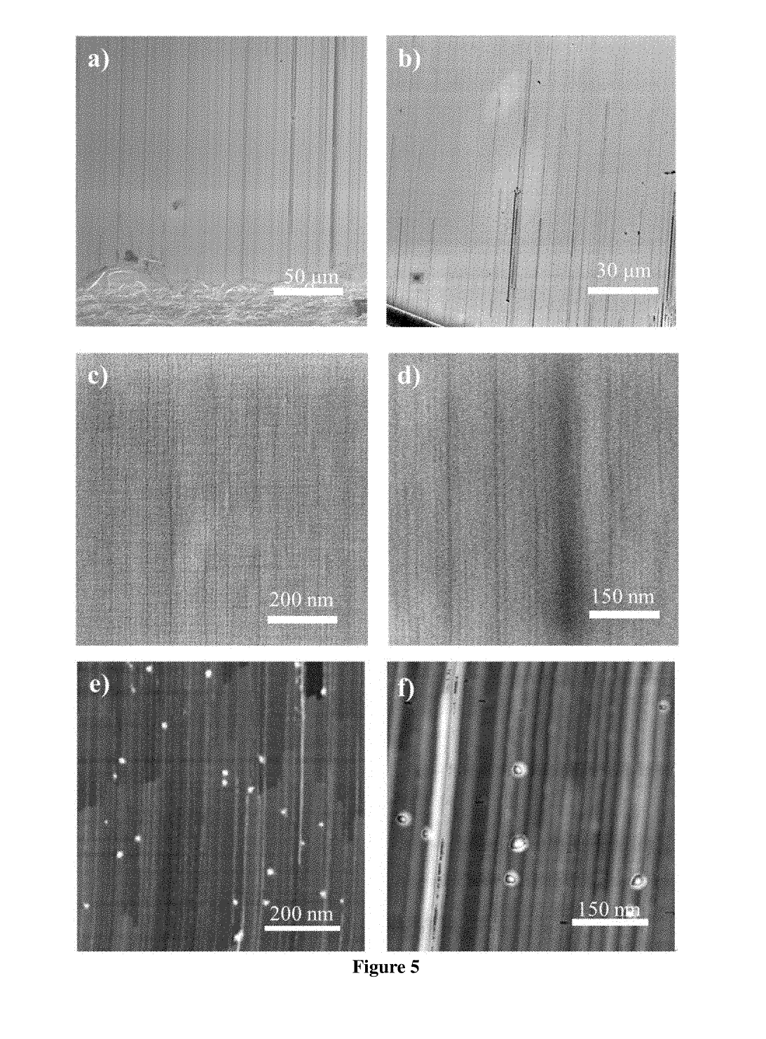

The growth result of the ultra-high density single-walled carbon nanotube horizontal array obtained in this example is shown as FIG. 5. It can be seen from this figure, that both AFM and SEM images clearly indicate that the density of single-walled carbon nanotube horizontal array obtained in this example exceeds 130 tubes/micrometer, which is the highest density of single-walled carbon nanotube horizontal array by direct growth reported at present in the world.

### Example 3. The Mechanism Analysis of the Preparation Method of the Ultra-High Density Single-Walled Carbon Nanotube Horizontal Array

1) the analysis and validation of the incorporating mechanism in the preparation method of the ultra-high density single-walled carbon nanotube horizontal array;

XPS depth analysis is conducted on the annealed single crystal growth substrate obtained in step 4) of example 1, as shown in FIG. 5, Fe element is found underneath the surface of the alumina single crystal substrate, obviously, Fe catalyst can indeed get into the alumina single crystal substrate for storing by the above annealing method.

2) the analysis and validation of the release mechanism in the preparation method of the ultra-high density single-walled carbon nanotube horizontal array;

Annealing treatment is performed with hydrogen on the single crystal growth substrate obtained in step 4) of example 1 in a tube furnace, the flow gas of hydrogen being 100 sccm, and the treatment time (that is, hydrogen reduction time) is 0 min, 5 min, 10 min, 30 min, as shown in FIG. 7b). There is almost no any catalyst particle on the surface of the substrate, also further demonstrating that the catalyst is incorporated.

As shown in FIGS. 7c), 7d), and 7e), with the increase of the hydrogen reduction time, more and more catalyst particles are released to the surface of the substrate, demonstrating that the catalyst can be and gradually released.

3) the analysis and validation of the growth process in the preparation method of the ultra-high density single-walled carbon nanotube horizontal array;

The single crystal growth substrate obtained in step 4) of example 1 is placed into a chemical vapor deposition system to conduct the growth of the carbon nanotubes, and the growth time is 5 min, 10 min, and 30 min, respectively.

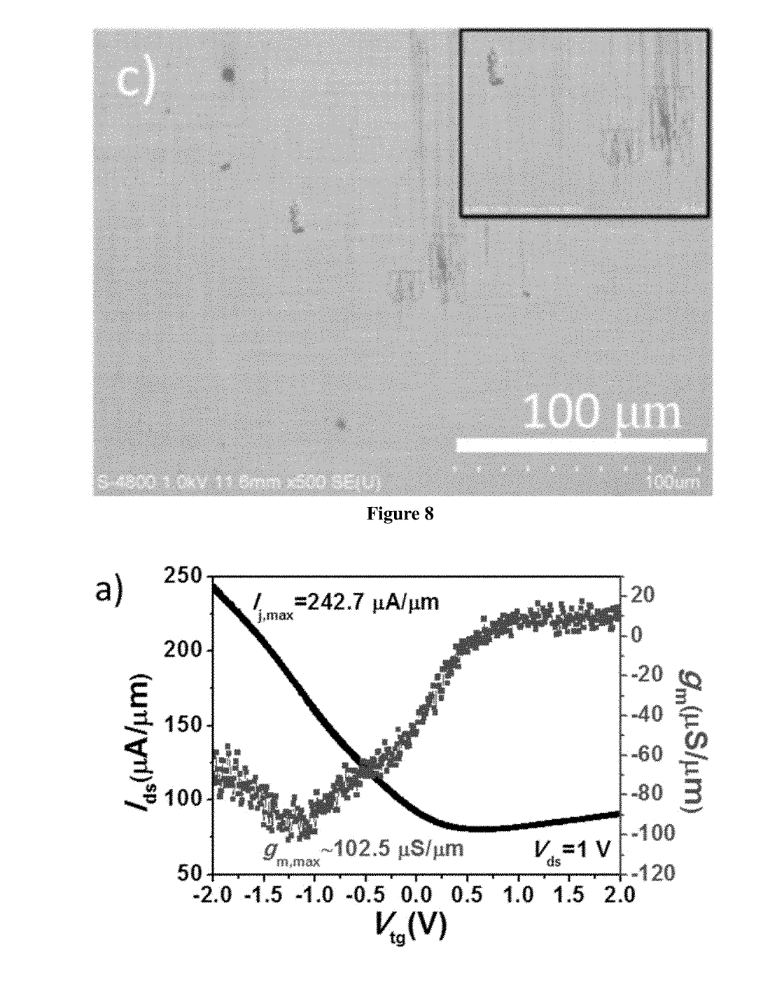

As shown in FIG. 8, in FIG. 8a), the growth time is 5 min, and the density of the carbon nanotubes is less than 1 tube/micrometer;

in FIG. 8b), the growth time is 10 min, and the density of the carbon nanotubes is 10 tubes/micrometer;

in FIG. 8c), the growth time is 30 min, and the density of the carbon nanotubes is more than 100 tubes/micrometer.

It can be seen that with the extension of the growth time, the density of the carbon nanotube array also gradually increases, and the mechanism of growing with catalyst precipitating in the preparation method of the ultra-high density single-walled carbon nanotube horizontal array is validated in combination with that with the increase of hydrogen reduction time, more and more catalyst particles precipitate out in step 2) of example 3.

### Example 4. The Characterization of Electric Performance of the Ultra-High Density Single-Walled Carbon Nanotube Horizontal Array

According to the following preparation flows, the ultra-high density single-walled carbon nanotube horizontal array provided by the present invention is prepared into a field effect transistor device:

using “U-shaped gate self-alignment” process: first spin-coating two electron beam photoresists PMMA with different sensitivities on a-plane a alumina single crystal substrate which is bestrewn with the ultra-high density carbon nanotube array obtained in example 1; achieving a “U” shaped channel on the surface of the substrate coated with photoresists via a standard micro-nano device processing process such as electron beam lithography, developing, fixing, etc., by means of the difference of the sensitivity of bi-layer photoresist; and sequentially depositing a 12 nm dielectric layer of hafnium oxide and a 70 nm titanium electrode layer within the via atomic layer deposition and electron beam evaporation processes, then the preparation of top gate of field effect transistor is completed via standard process flows such as lifting off, removing of photoresist, etc.;

then, achieving the patterning of source and drain electrodes on the surface of the substrate coated with photoresists again via the flows such as spin-coating photoresist (single layer), electron beam lithography, developing, fixing, etc., and sequentially depositing a 0.5 nm adhesive layer of titanium, a 30 nm electrode layer of palladium and a 50 nm electrode layer of gold within the area which is pre-patterned, and then the preparations of source and drain electrodes of field effect transistor are completed via the flows such as such as lifting off, removing of photoresist, etc.;

achieving the patterning of working area of carbon nanotube array device on the surface of the substrate coated with photoresist by using the above standard micro-nano device processing process, and the carbon nanotube array of other areas except for working area within the substrate of the device is etched by reactive ion beam etching to prevent the device from short circuit or electric leakage in the test process, then removing the electron beam photoresist which is coated on the substrate by removing of photoresist;

finally, 10 nm palladium electrode connection layer is filled in the voids among source electrode, drain electrode, and gate electrode via an electron beam evaporation and by using “self-alignment” effect of “U-shaped top gate”, so as to maximally eliminate the parasitic resistance among source electrode, drain electrode, and gate electrode, and the preparation of field effect transistor with a top gate structure based on carbon nanotube array is finally completed.

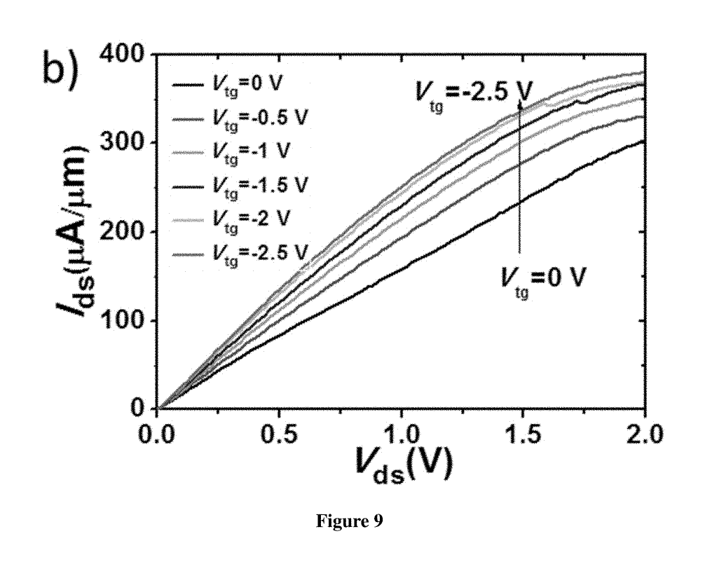

the performance of this field effect transistor device is tested, and the result is shown as FIG. 9, wherein the channel length is 1.2 μm, the channel width is 12 μm, its on-current density is up to 380 μA/μm, and the transconductance is up to 102.5 μS/μm, both are the highest level in the carbon nanotube field effect transistor at present in the world, and it also reflect the high quality and high density of ultra-high density single-walled carbon nanotube horizontal array prepared by the present invention from another point of view.

Of particular note is that, the above described examples are only the preferred embodiments of the present invention, and for those skilled in the art, several improvements and modifications derived from the technical ideas of the present invention should be considered as being within the patent protection scope of the present invention.

### INDUSTRIAL APPLICATION

The preparation method of ultra-high density single-walled carbon nanotube horizontal array provided by the present invention possesses advantages of simple sample preparation, convenient operation, low cost, and large-scale preparation compared with the general preparation methods. Moreover, by using this growth mode, it is promising to achieve the controllable preparation of single-walled carbon nanotube horizontal array with high density through choosing different catalysts and substrates, therefore, the methods of the present invention possess extreme broad application prospects.

1. A method for preparing ultra-high density single-walled carbon nanotube horizontal array, comprising the following steps:
loading a catalyst on a single crystal growth substrate; after annealing, introducing hydrogen into a chemical vapor deposition system to conduct a reduction reaction of the catalyst; and maintaining the introduction of the hydrogen to conduct an orientated growth of the single-walled carbon nanotubes, then after the growth, the ultra-high density single-walled carbon nanotube horizontal array is directly obtained on the single crystal growth substrate.

2. The method of claim 1, wherein a material constituting the single crystal growth substrate is ST-cut quartz, R-cut quartz, a-plane α alumina, r-plane α alumina or magnesium oxide;
the catalyst is selected from a metal nanoparticle, wherein a metal element in the metal nanoparticle is selected from at least one of Fe, Co, Ni, Cu, Au, Mo, W, Ru, Rh, and Pd; the particle size of the catalyst is 1 nm-3 nm.

3. The method of claim 1, further comprising, conducting a pretreatment of the single crystal growth substrate before loading the catalyst; wherein
the pretreatment particularly comprises the following steps: the single crystal growth substrate is successively ultrasonicated in secondary water, acetone, ethanol, and secondary water respectively for 10 min; after blow-dried with nitrogen, a temperature of pretreatment is evaluated to 1000° C.-1500° C. from room temperature within 1.5 h-3 h and is kept constant for 4 h-8 h, then the temperature of pretreatment is decreased to 300° C. within 3 h-10 h, followed by natural cooling to room temperature.

4. The method of claim 2, wherein in the step of loading the catalyst, a loading method comprises spin-coating or drop-coating a salt solution of the catalyst onto the surface of the single crystal growth substrate;
in the salt solution of the catalyst, solutes are hydroxide or salt of the metal element, particularly Fe(OH)₃ or (NH₄)₆Mo₇O₄;
in the salt solution of the catalyst, a solvent is selected from at least one of ethanol, water and acetone;
in the salt solution of the catalyst, a concentration of the salt solution of the catalyst is 0.01-0.5 mmol/L;
in the spin-coating method, a rotation speed of the spin-coating is 1000-5000 rpm;
a spin-coating time is 1-10 min.

5. The method of claim 1, wherein the annealing process comprises the following steps:
in air atmosphere, a temperature of annealing is evaluated to annealing temperature from room temperature within 1.5 h-3 h, and is kept constant for 4 h-48 h, then the annealing temperature is cooled to 300° C. within 3 h-10 h, followed by natural cooling to room temperature;
the annealing temperature is 1100° C.; and the time for constant temperature is 8 h.

6. The method of claim 1, wherein in the reduction reaction step of the catalyst, a reduction atmosphere is hydrogen atmosphere; a gas flow of hydrogen is 30 sccm-300 sccm.
a reduction time is 1 min-30 min; in the step of orientated growth of the single-walled carbon nanotubes, carbon sources used are CH₄, C₂H₄, or ethanol;
a gas flow of the carbon source is 10 sccm-200 sccm;
a growth time is 10 s-1 h
in each of the reduction reaction step and the orientated growth step of the lattice, a temperatures is 600° C. -900° C.
used carrier gases are both Ar; and a gas flow of the Ar is 50 sccm-500 sccm.

7. The method of claim 1, wherein the method further comprises the following steps: after the orientated growth step of the single-walled carbon nanotubes, cooling the system;
the cooling is natural cooling or program-controlled cooling.

8. An ultra-high density single-walled carbon nanotube horizontal arrays are prepared according to the method of claim 1.

9. The method of claim 8, wherein the ultra-high density single-walled carbon nanotube horizontal arrays are characterized in that the density of the ultra-high density single-walled carbon nanotube horizontal arrays is 50 tubes/micrometer-150 tubes/micrometer.

10. A field effect transistor device contains the ultra-high density single-walled carbon nanotube horizontal arrays of claim 8;

11. The method of claim 4, wherein the concentration of the salt solution of the catalyst is 0.01-0.05 mmol/L.

12. The method of claim 4, wherein rotation speed of the spin-coating is 2000 rpm.

13. The method of claim 4, wherein the spin-coating time is 1 min.

14. The method of claim 9, wherein the gas flow of hydrogen is 100 sccm-300 sccm.

15. The method of claim 9, wherein the reduction time is 5 min.

16. The method of claim 9, wherein the gas flow of the carbon source is 50 sccm-150 sccm.

17. The method of claim 9, wherein the growth time is 10 min-30 min.

18. The method of claim 9, wherein the temperature in each of the reduction reaction step and the orientated growth step of the lattice is 830° C.-850° C.

19. The method of claim 9, wherein the gas flow of the Ar is 300 sccm.
